(19) United States
(12) Patent Application Publication
(10) Pub. No.: US 2016/0320697 A1
(43) Pub. Date: Nov. 3, 2016

(54) IMPRINT APPARATUS, IMPRINT METHOD, AND ARTICLE MANUFACTURING METHOD

(71) Applicant: CANON KABUSHIKI KAISHA

(72) Inventors: Tosiya Asano, Utsunomiya-shi (JP); Noriyasu Hasegawa, Utsunomiya-shi (JP); Yosuke Murakami, Utsunomiya-shi (JP)

(21) Appl. No.: 15/106,900

(22) PCT Filed: Jan. 20, 2015
(86) PCT No.: PCT/JP2015/051947

§ 371 Date: Jun. 21, 2016

(30) Foreign Application Priority Data
Feb. 4, 2014 (JP) 2014-019767

(51) Int. Cl. G03F 7/00; B29C 59/00; B29C 59/02; G03F 7/16; G03F 9/00

(52) U.S. Cl. CPC G03F 7/0002; G03F 7/161; G03F 9/7088; B29C 59/02; B29C 59/002

(57) ABSTRACT

An imprint apparatus includes: a substrate stage; a mold stage; a detector configured to detect a relative position of a substrate to a mold in a direction parallel to a surface of the substrate; a vibration unit configured to transmit a vibration to the imprint material; and a controller configured to control the imprint process to align the substrate and the mold based on a detection result by the detector while the vibration unit transmits the vibration to the imprint material after bringing the imprint material and the mold into contact with each other.

### TECHNICAL FIELD

The present invention relates to an imprint apparatus, an imprint method, and an article manufacturing method.

### BACKGROUND ART

An imprint technique is a technique of forming a pattern on a substrate (wafer) by using a mold on which a pattern has been formed. An example of the imprint technique is a photo-curing method. In the imprint technique using this photo-curing method, a fluidable resin as an imprint material is supplied to a shot region which is an imprint region on the substrate. The supplied resin is cured by irradiation with light in a state in which a pattern of a mold is pressed against (imprinted on) the resin. The pattern of the cured resin is transferred onto the substrate by separating (releasing) the mold from the resin.

In the manufacture of a semiconductor chip, it is necessary to accurately align the substrate and the mold when imprinting the mold on the resin on the substrate. As a method of aligning the substrate and the mold in an imprint apparatus, a so-called die-by-die method is known in which alignment is performed by detecting a mark formed on the mold and a mark formed in each shot region of the substrate.

Japanese Patent Laid-Open No. 2008-522412 describes an imprint apparatus which calculates a relative displacement between a mold and a substrate by detecting an alignment mark, and relatively moves stages (a mold stage and a substrate stage).

In an imprint technique, a gap between a mold and a substrate at the time of imprinting is 1 μm or less. A resin which fills this gap has viscoelasticity having both characteristics of viscosity and elasticity. If both of the mold and the substrate are relatively moved for their alignment at the time of imprinting, the viscoelasticity of the resin causes a force to act between them. Since this force also acts on a mold pattern, the micropattern may deform. The relative moved amount between the mold and the substrate at the time of alignment changes for each shot region. Therefore, a force acting on a portion between the mold and the substrate, and mold pattern deformation also vary for each shot region. For example, in the imprint of a semiconductor chip, a defective chip is produced, resulting in a decrease in a yield.

### SUMMARY OF INVENTION

The present invention provides an imprint apparatus which reduces the deformation of a mold pattern.

The present invention in its one aspect provide an imprint apparatus for performing an imprint process of forming a pattern on a substrate by bringing a mold and an imprint material supplied onto the substrate into contact with each other, the apparatus comprising: a substrate stage configured to hold the substrate; a mold stage configured to hold the mold; a detector configured to detect a relative position of the substrate to the mold in a direction parallel to a surface of the substrate; a vibration unit configured to transmit a vibration to the imprint material; and a controller configured to control the imprint process to align the substrate and the mold based on a detection result by the detector while the vibration unit transmits the vibration to the imprint material after bringing the imprint material and the mold into contact with each other.

Further features of the present invention will become apparent from the following description of exemplary embodiments with reference to the attached drawings.

### BRIEF DESCRIPTION OF DRAWINGS

FIG. 1 is a conceptual view showing an imprint apparatus according to the first embodiment;

FIG. 2 is a block diagram showing the control system of the imprint apparatus;

FIG. 3 is a graph for explaining the characteristic of a force acting on a portion between the mold and the substrate of the imprint apparatus according to a conventional technique;

FIG. 4 is a graph for explaining the characteristic of a force acting on a portion between the mold and the substrate of an imprint apparatus according to the second embodiment;

FIG. 5 is a side view in the vicinity of a mold of an imprint apparatus according to the third embodiment; and

FIG. 6 is a view showing the mold of the imprint apparatus according to the third embodiment viewed from the lower side.

### DESCRIPTION OF EMBODIMENTS

### First Embodiment

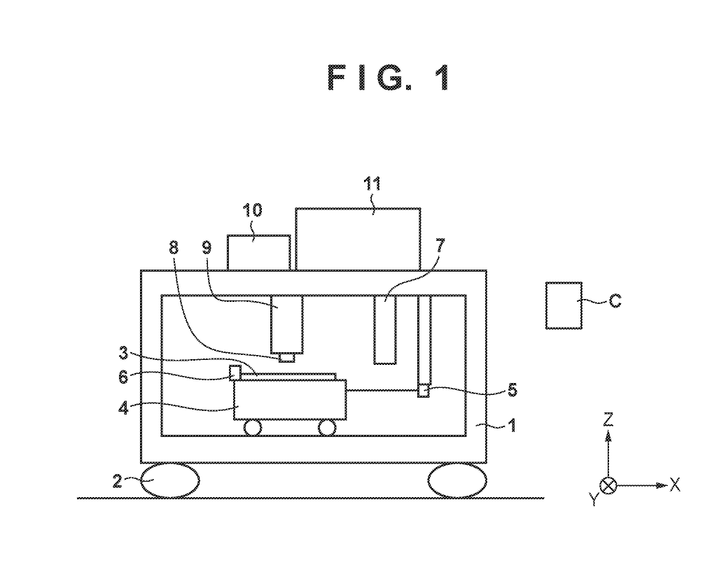

The first embodiment of the present invention will be described below. FIG. 1 shows the overview of an imprint apparatus according to the first embodiment. A main body 1 of the imprint apparatus is arranged on a floor through an anti-vibration mechanism 2 with three or four legs each using an air spring or the like. A substrate (wafer) 3 is held on a substrate stage (wafer stage) 4 by a wafer chuck (not shown). The wafer stage 4 has a stroke in an X direction and a Y direction enough to be able to perform an imprint process on the entire surface of the wafer 3 and move the wafer 3 to an exchange position where loading/unloading is performed by a wafer exchange hand (not shown).

Although the wafer stage 4 is illustrated simply as one stage and wheels in FIG. 1, it actually has a structure as will be described below. As the wafer stage 4, a stage is used which mounts a fine moving stage having a short stroke and high positioning accuracy on a coarse moving stage having a long stroke in the X direction and the Y direction. The arrangement of the wafer stage 4 is not limited to this, and can use a high-accurate positioning stage which is generally used in a semiconductor exposure apparatus wafer stage.

A laser interferometer 5 provided in the main body 1 and a reflecting mirror (not shown) which is provided on the wafer stage 4 and reflects a laser beam measures the position of the wafer stage 4 in the X direction. Similarly, a laser interferometer which measures the position of the wafer stage 4 in the Y direction is also provided. A scale substrate provided in the main body 1 and an encoder system constituted by an optical devices provided on the wafer stage 4 may be used to measure the position of the wafer stage 4.

A vibration unit 6 which generates a high-frequency vibration and transmits it to the resin is arranged on the wafer stage 4. A photo-curing type resin (imprint material) used at the time of an imprint process is supplied onto the wafer 3 by a dispenser 7 provided in the main body 1. A mold 8 (also referred to as a template) on which a micropattern has been formed is held by a mold stage (imprint head mechanism) 9 arranged in the main body 1. The mold stage 9 can move the mold 8 in a Z direction while holding it. Here, as shown in FIG. 1, a direction in which the mold 8 held by the mold stage 9 is pressed against the wafer 3 onto which the resin is supplied is set as the Z direction. A direction perpendicular to the direction in which the mold 8 is pressed against the wafer 3 and parallel to the surface of the wafer 3 is set to the X direction and the Y direction.

A detector 10 provided in the main body 1 detects the relative position of the wafer 3 to the mold 8 in the direction (the X direction and the Y direction) parallel to the surface of the wafer 3. On the wafer 3, an alignment mark is transferred to the position in each shot region by a previous process step. An alignment mark corresponding to this is also provided on the mold 8. The detector 10 irradiates the mold 8 and the wafer 3 with alignment light to detect their alignment marks by an alignment scope. A controller C calculates the relative displacement between the mold 8 and the wafer 3 by performing an image process on the detection result by the alignment scope. An irradiation system 11 which irradiates the resin with ultraviolet rays to cure is mounted on the main body 1.

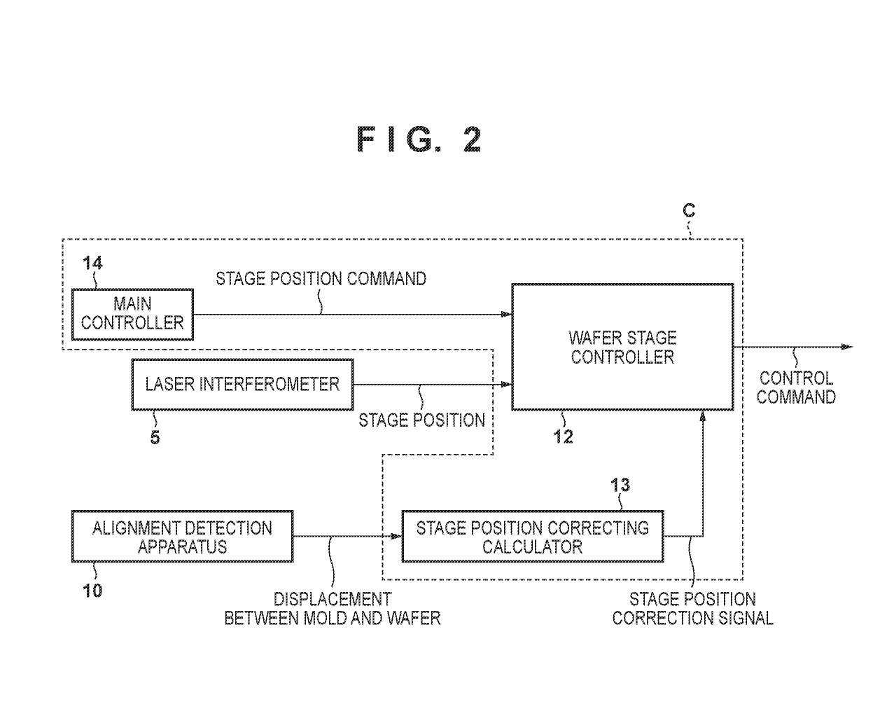

FIG. 2 is a block diagram showing the control system of the imprint apparatus. A wafer stage controller 12 performs the position control of the wafer stage 4. The wafer stage controller 12 uses a feedback control system which feedbacks a deviation obtained by subtracting the stage position measured by the laser interferometer 5 from a stage position command sent from a main controller 14. The displacement between the mold 8 and the wafer 3 output from the detector 10 is input to a stage position correcting calculator 13 and sent to the wafer stage controller 12 as a stage position correction signal. The wafer stage controller 12 performs control calculation by setting a position obtained by adding the stage position correction signal to the above-described stage position command as the target position of the wafer stage 4. A control command as a result of the control calculation is sent to an actuator which drives the wafer stage 4 to be a driving force, and performs positioning control on the wafer stage 4. These control systems perform complex calculations and are formed by a digital computer.

Respective operations at the time of the imprint process will now be described. The wafer stage 4 moves to the exchange position of the wafer 3, and the wafer 3 is mounted on a wafer chuck (not shown) by a wafer exchange hand (not shown). The controller C moves the wafer stage 4 such that a shot region on the wafer 3 which performs the imprint process is located under the dispenser 7. The dispenser 7 supplies the resin to the wafer 3. After the controller C moves the wafer stage 4 such that the shot region is located under the mold 8, the mold stage 9 lowers the mold 8 to perform imprint. This imprint is an operation of filling the pattern formed on the mold 8 with the resin by driving the mold stage 9 in the Z direction to bring the mold 8 into contact with the resin on the wafer. In an initial imprint, displacement occurs in the relative position between the mold 8 and the wafer 3 in the horizontal direction (the X direction and the Y direction). The detector 10 detects this displacement as described above. A stage correction signal generated by the stage position correcting calculator 13 is sent to the wafer stage controller 12.

If the wafer stage 4 is moved at the time of imprinting, the viscoelasticity of the resin which fills a portion between the mold 8 and the wafer 3 causes a force to act between them. The force also acts between the mold 8 and the wafer 3 because a force is generated between the wafer 3 and the resin by moving the wafer stage 4 and a reaction force to the resin is transmitted to the mold. It has been found that this viscoelasticity is reduced by transmitting a high-frequency vibration to the resin. By a command from the main controller 14, the vibration unit 6 generates a high-frequency vibration to vibrate the resin at a high frequency, thereby reducing the viscoelasticity of the resin. The frequency and the magnitude of the high-frequency vibration are determined by the type of resin to be used and the spacing between the surfaces of the mold 8 and the wafer 3. It is therefore possible to measure the force acting between the mold 8 and the resin using the driving force of the wafer stage controller 12 by changing the frequency and the magnitude of the high-frequency vibration generated by the vibration unit 6 in advance, and determine a value to be actually used. Furthermore, the frequency can be 1 kHz or more because the frequency of 1 kHz or less may have an influence on the feedback system of the wafer stage controller 12.

The alignment scope of the detector 10 uses an optical sensor (not shown). The optical sensor accumulates detection light for a predetermined time and converts it into an electrical signal. As a result, an average value within an accumulation time is output. Therefore, with the high frequency of 1 kHz or more, the high-frequency vibration has no influence on a detection result by the detector 10 by virtue of this average effect. The alignment between the mold 8 and the wafer 3 is completed by moving the wafer stage 4 during vibration at a high frequency. The mold 8 and the wafer 3 are relatively moved in a state in which the viscoelasticity of the resin is extremely small. This makes it possible to prevent the force from being generated between the mold 8 and the resin at the time of alignment. After the completion of the alignment, the high-frequency vibration stops. After the resin is irradiated with ultraviolet rays by the irradiation system 11 and cured, the mold 8 is separated (released) from the cured resin by expanding the spacing between the wafer 3 and the mold 8, and an imprint process for one shot region is completed. Subsequently, the sequence of resign supply, imprint, alignment during vibration, curing, and release is performed repeatedly for each shot region. Each shot region performs alignment during vibration. As a result, the force acting between the mold 8 and the resin at the completion of the alignment, and thus a force variation are reduced. After an imprint process for the entire surface of the wafer is completed, the wafer stage 4 moves to the wafer exchange position and collects the imprinted wafer 3 by the wafer exchange hand. The next wafer 3 is mounted on the wafer chuck, and an imprint sequence for the entire surface of the wafer is performed again.

The vibration unit 6 is provided on the wafer stage 4. However, it may be provided on the mold stage 9 as long as the high-frequency vibration is transmitted to the resin. The arrangement has been employed here in which the wafer stage 4 is moved when aligning the mold 8 and the wafer 3. However, the arrangement may be employed in which a moving mechanism in the X and Y directions is provided on the mold stage 9 to move the mold 8. In this case, the mold stage 9 includes a position control system in the X and Y directions, and also receives the stage position correction signal by the stage position correcting calculator 13. Alignment of the mold 8 and the wafer 3 can be performed by moving at least one of the wafer stage 4 and the mold stage 9. Furthermore, the wafer stage 4 may be vibrated directly at a high frequency without providing the vibration unit 6 separately. In this case, a vibration signal is superimposed on a positioning signal for the control command from the wafer stage controller 12.

### Second Embodiment

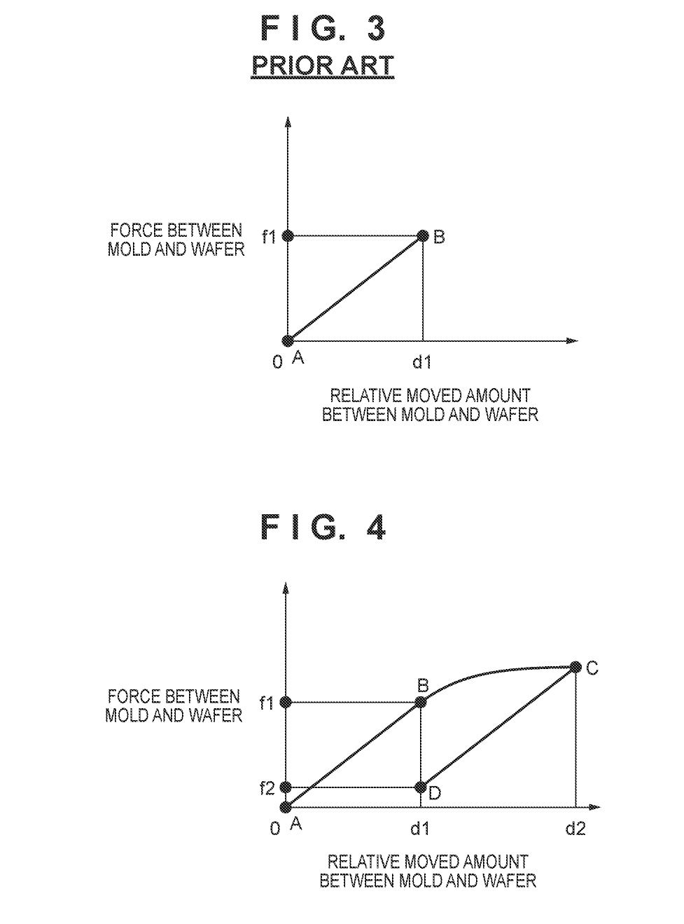

An imprint apparatus according to the second embodiment is obtained by omitting a vibration unit 6 from the apparatus shown in FIG. 1, and the illustration thereof will be omitted. FIGS. 3 and 4 show the characteristic of a force between a mold 8 and a wafer 3. At the start of imprinting, a mold stage 9 is moved only in a Z direction in a state in which a wafer stage 4 is made stand still. Therefore, the mold 8 and the wafer 3 are not moved relatively in an X and a Y directions, and thus the force between the mold 8 and the wafer 3 is zero. A point A in FIG. 3 indicates this state. The displacement between the mold 8 and the wafer 3 measured by a detector 10 is set to d1. The wafer stage 4 is moved by a wafer stage position correction signal by a stage position correcting calculator 13 and a wafer stage controller 12. As a result, the displacement between the mold 8 and the wafer 3 is eliminated when the relative moved amount between the mold 8 and the wafer 3 becomes d1.

A point B in FIG. 3 indicates this state. At this time, the movement of the wafer stage 4 is extremely slow. Therefore, out of the viscoelasticity of a resin, a viscosity resistance force is hardly generated but a characteristic of almost elasticity appears. Also in this embodiment, a force is generated between the wafer 3 and the resin by moving the wafer stage 4, and a force (f1) is also generated between the mold 8 and the wafer 3 because a reaction force to the resin is transmitted to the mold 8. In a region (first region) from the point A to the point B, therefore, the relationship between the force between the mold 8 and the wafer 3, and the relative moved distance between the mold 8 and the wafer 3 exhibits linearity. An irradiation system 11 performs irradiation immediately after the completion of alignment in a point-B state. Therefore, the resin is cured in a state in which the force f1 acts on the mold 8. The displacement between the mold 8 and the wafer 3 at the start of imprinting changes for each shot region, and thus a force acting on the mold 8 at the end of alignment also change. Because of this phenomenon, the transfer accuracy of a pattern formed on the mold 8 to the wafer 3 varies for each shot region, and a defective chip is produced, resulting in a decrease in a yield.

FIG. 4 shows a case in which the present invention is employed. The stage position correcting calculator 13 generates, for the displacement d1 between the mold 8 and the wafer 3, a stage position correction signal which temporarily moves to the second position as d2 beyond the first position as d1, and then returns to the first position as d1. Note that the relative moved amount d1is the relative moved amount within the first region, and the relative moved amount d2 is the relative moved amount within the second region. As the relative moved amount between the mold 8 and the wafer 3 increases, the viscoelasticity of the resin changes, and an increase in the force between the mold 8 and the wafer 3 decreases with respect to the relative moved amount. When the relative moved distance between the mold 8 and the wafer 3 is about d2, the force acting between the mold 8 and the wafer 3 belongs to the second region where no linearity is exhibited to the relative moved distance. If a relative moving direction is reversed from the second position of a point C where the relative moved amount between the mold 8 and the wafer 3 becomes d2, and the wafer stage 4 is driven to set the relative moved amount to d1, the viscoelasticity of the resin changes again. At this time, a force variation increases relative to the relative moved amount between the mold 8 and the wafer 3. That is, the slope of each line in FIGS. 3 and 4 indicates a viscoelastic spring characteristic, and the steeper the slope, the more significant the spring characteristic. The spring characteristic when moving from the point A to the point B and the spring characteristic when moving from the point C to a point D have almost the same value, thus each being indicated by a parallel straight line. A force between the mold 8 and the resin at the point D where the displacement between the mold 8 and the wafer 3 is eliminated will be f2. The force f2 is much smaller than the force f1 obtained when moving from the point A to the point B without employing the present invention.

The characteristics of the relative moved amount between the mold 8 and the wafer 3, and the force between the mold 8 and the wafer 3 shown in FIG. 4 change depending on, for example, the type of resin to be used, the spacing between the mold 8 and the wafer 3, and the relative moving speed between the mold 8 and the wafer 3. Therefore, the characteristics are, in advance, obtained by experiment, converted into numerical values, and stored in the nonvolatile memory of a digital calculator. Then, the stage position correcting calculator 13 determines, based on this, the value of d2 with respect to d1. In accordance with the displacement between the mold 8 and the wafer 3 at the time of initial imprinting which changes for each shot, d2 is set for each shot region such that the force f2 between the mold 8 and the wafer 3 at the end of alignment becomes small. As a result, a force acting on the mold 8 when curing the resin, and thus a force variation are reduced. This can suppress a reduction in the transfer accuracy of a pattern formed on the mold 8 to the wafer 3.

The arrangement has been employed here in which the wafer stage 4 is moved when aligning the mold 8 and the wafer 3. As in the first embodiment, however, the arrangement may be employed in which a moving mechanism in the X and Y directions is provided on the mold stage 9 to move the mold 8. Furthermore, in both of the first and the second embodiments described above, the arrangement has been employed in which the mold stage 9 is moved in the Z direction when bringing (imprinting) the mold 8 and the resin on the wafer 3 into contact with each other. However, the arrangement may be employed in which a moving mechanism in the Z direction is provided on the wafer stage 4 to move the wafer 3. Furthermore, the mold 8 and the resin on the wafer 3 may be brought into contact with each other by moving the wafer stage 4 and the mold stage 9 sequentially or simultaneously.

### Third Embodiment

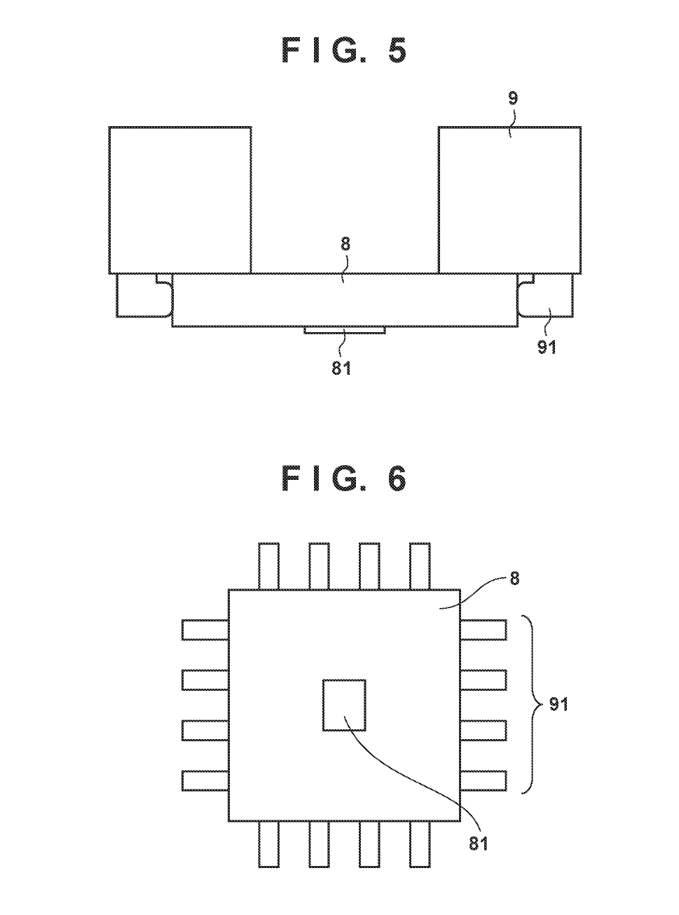

An imprint apparatus according to the third embodiment includes a mold stage 9 of an imprint apparatus shown in FIG. 1 which includes a shape correcting mechanism 91. FIGS. 5 and 6 show the shape correcting mechanism 91 provided to surround a mold held by the mold stage 9 and the outer periphery side surface of the mold 8. The shape correcting mechanism 91 is an apparatus which corrects the shape of a pattern portion 81 formed on the mold 8, and formed by an actuator and a link mechanism. The mold 8 may be moved in an X direction and a Y direction using this shape correcting mechanism.

When the shape correction of a pattern is required at high accuracy, the shape of the pattern portion 81 is corrected to match the shape of the pattern portion 81 on the mold 8 with the shape of a shot region on a substrate in a state in which the mold 8 and a resin are brought into contact with each other. A detector 10 can obtain the mismatch between the shape of the pattern portion 81 and the shape of the shot region on the substrate by detecting a plurality of alignment marks within a shot. The correction distance of the pattern portion 81 (the driving amount of the shape correcting mechanism 91) can be determined by obtaining the displacement of the alignment marks detected by the detector 10. The driving amount (driving distance) of the shape correcting mechanism 91 can be obtained in accordance with the obtained deformation amount (correction value) of the pattern portion 81. If the shape correcting mechanism 91 corrects the shape of the pattern portion 81, the viscoelasticity of the resin causes a force to act between the mold and the resin. Since this force also acts on a mold pattern, the micropattern may deform. Also, when the shape correcting mechanism 91 corrects the shape of the pattern portion 81, the driving amount of the shape correcting mechanism 91 changes for each shot region. Accordingly, a force acting between the pattern of the mold 8 and the resin at the end of shape correction also changes.

To cope with this, as the same characteristic as in FIG. 4, the relationship between the driving amount (driving distance) of the shape correcting mechanism 91 and a force between the mold 8 and a wafer 3 is obtained in advance. The force acting on the mold 8 at the end of shape correction and a force variation can be reduced by, based on the relationship, temporarily driving a predetermined driving amount which exceeds a target driving amount (target driving position), and then returning it to the target driving amount. As a result, it is possible to suppress a reduction in the transfer accuracy of a pattern formed on the mold 8 to the wafer 3.

Furthermore, the shape correcting mechanism 91 may be driven to correct the shape of the pattern portion 81 on the mold 8 while vibrating a wafer stage 4 at a high frequency as has been described in the first embodiment. Alignment by the wafer stage 4 may be performed in parallel with correction of the shape of the pattern portion 81, or alignment by shape correction may be performed after the alignment by the wafer stage 4 is performed.

Also, the shape correcting mechanism 91 may correct the shape of the pattern portion 81 after, as in the second embodiment, alignment is performed by driving the wafer stage 4 by a predetermined driving distance beyond a target driving position, and then returning it to a target position. The alignment by the wafer stage 4 may be performed in parallel with the correction of the shape of the pattern portion 81.

In all the embodiments described above, the characteristics of the relative moved amount between the mold 8 and the wafer 3, and the force between the mold 8 and the wafer 3 shown in FIG. 4 change depending on, for example, the spacing between the mold 8 and the wafer 3. When imprinting the mold 8 onto the wafer 3 held by a wafer chuck, the spacing between the mold 8 and the wafer 3 can be set to a predetermined spacing by the surface tension of the resin which fills a portion between the mold 8 and the wafer 3. In practice, however, the spacing between the mold 8 and the wafer 3 may change for each shot depending on wafer flatness. Therefore, a height sensor (not shown) measures the height of the wafer 3, and based on that measurement result, the distribution of the spacing between the mold 8 and the wafer 3 is measured. All the heights of the wafer 3 may be measured on the entire surface of the wafer. Alternatively, some heights may be measured and then values between the measured heights may be interpolated. Based on that distribution information, the characteristics of the relative moved amount between the mold 8 and the wafer 3, and the force between the mold 8 and the wafer 3 are obtained. Likewise, the characteristics of the driving amount (driving distance) of the shape correcting mechanism 91, and the force between the mold and the wafer are obtained. These characteristics may be stored in the above-described nonvolatile memory to use for reference at the time of alignment. This makes it possible to further suppress the reduction in the transfer accuracy of the pattern formed on the mold 8 to the wafer 3.

[Article Manufacturing Method]

A manufacturing method of a device (a semiconductor integrated circuit device, a liquid crystal display device, an MEMS, or the like) as an article includes a step of transferring (forming) a pattern onto a substrate (a wafer, a glass plate, a film-like substrate, or the like) using the above-described imprint apparatus. The manufacturing method can also include a step of etching the substrate onto which the pattern has been transferred. Note that when manufacturing another article such as a patterned media (storage medium) or an optical element, the manufacturing method can include, instead of the etching step, another processing step of processing the substrate onto which the pattern has been transferred.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-019767, filed Feb. 4, 2014, which is hereby incorporated by reference herein in its entirety.

1. An imprint apparatus for performing an imprint process of forming a pattern on a substrate by bringing a mold and an imprint material supplied onto the substrate into contact with each other, the apparatus comprising:
a substrate stage configured to hold the substrate;
a mold stage configured to hold the mold;
a detector configured to detect a relative position of the substrate to the mold in a direction parallel to a surface of the substrate;
a vibration unit configured to transmit a vibration to the imprint material; and
a controller configured to control the imprint process to align the substrate and the mold based on a detection result by the detector while the vibration unit transmits the vibration to the imprint material after bringing the imprint material and the mold into contact with each other.

2. The apparatus according to claim 1, wherein the vibration unit is arranged on the substrate stage.

3. The apparatus according to claim 1, wherein the vibration unit is arranged on the mold stage.

4. The apparatus according to claim 1, wherein the controller aligns the substrate and the mold by moving at least one of the substrate stage and the mold stage relatively in the direction parallel to the surface of the substrate.

5. The apparatus according to claim 1, wherein the controller determines a frequency and a magnitude of the vibration based on at least one of a spacing between the surface of the substrate and a surface of the mold which is in contact with the imprint material, and a type of an imprint material to be used.

6. The apparatus according to claim 1, wherein the vibration unit transmits a vibration not less than 1 kHz to the imprint material.

7. The apparatus according to claim 1, further comprising a shape correcting mechanism configured to correct a shape of the mold,
wherein the shape correcting mechanism deforms the shape of the mold into a predetermined shape, thereby aligning the substrate and the mold.

8. An imprint apparatus for performing an imprint process of forming a pattern on a substrate by bringing a mold and an imprint material supplied onto the substrate into contact with each other, the apparatus comprising:
a substrate stage configured to hold the substrate;
a mold stage configured to hold the mold;
a detector configured to detect a relative position of the substrate to the mold in a direction parallel to a surface of the substrate; and
a controller configured to control the imprint process,
wherein when the substrate stage is moved relatively to the mold stage in the direction in a state in which the imprint material is uncured and brought into contact with the mold, a relationship between a force generated between the mold and the substrate, and a relative moved distance of the substrate stage in the direction is that the relative moved distance exhibits linearity in a first region but no linearity in a second region which is larger than the first region, and
when positioning the substrate and the mold by moving the substrate stage to a first position relatively to the mold stage based on a detection result by the detector after bringing the imprint material and the mold into contact with each other, the controller relatively moves the substrate stage to a second position, within the second region, having a larger relative moved distance than the first position, and then relatively moves the substrate stage from the second position to the first position to position the substrate stage to the first position.

9. The apparatus according to claim 8, wherein the controller determines the second position based on at least one of a type of an imprint material to be used, a spacing between the surface of the substrate and a surface of the mold which is in contact with the imprint material, a relative moving speed of the substrate stage in the direction, and a relative moved distance to the first position.

10. The apparatus according to claim 1, wherein the controller moves the substrate stage in a direction perpendicular to a direction in which the mold is pressed against the substrate to position the substrate with respect to the mold.

11. The apparatus according to claim 1, wherein the controller moves the mold stage in the direction to position the substrate with respect to the mold.

12. An imprint apparatus for performing an imprint process of forming a pattern on a substrate by bringing a mold and an imprint material supplied onto the substrate into contact with each other, the apparatus comprising:
a detector configured to detect a relative position of the substrate to the mold in a direction parallel to a surface of the substrate;
a shape correcting mechanism configured to correct a shape of the mold; and
a controller configured to control the imprint process,
wherein a relationship between a correction distance of the shape correcting mechanism in the direction, and a force in the direction generated between the mold and the substrate owing to a viscoelasticity of the imprint material when correcting the shape of the mold in the direction using the shape correcting mechanism in a state in which the imprint material is uncured and brought into contact with the mold is that the correction distance exhibits linearity in a first region but no linearity in a second region which is larger than the first region, and
wherein assuming that a correction distance when correcting the shape of the mold using the shape correcting mechanism based on a detection result by the detector after bringing the imprint material and the mold into contact with each other is set to a first correction distance within the first region, the controller drives the shape correcting mechanism until the correction distance becomes a second correction distance within the second region, and then drives the shape correcting mechanism until the correction distance changes from the second correction distance to the first correction distance to correct the shape of the mold.

13. A method of manufacturing an article, the method comprising:
forming a pattern on a substrate using an imprint apparatus for performing an imprint process of forming the pattern on the substrate by bringing a mold and an imprint material supplied onto the substrate into contact with each other; and
processing the substrate on which the pattern has been formed to manufacture the article
wherein the imprint apparatus comprises
a substrate stage configured to hold the substrate,
a mold stage configured to hold the mold,
a detector configured to detect a relative position of the substrate to the mold in a direction parallel to a surface of the substrate,
a vibration unit configured to transmit a vibration to the imprint material, and
a controller configured to control the imprint process to align the substrate and the mold based on a detection result by the detector while the vibration unit transmits the vibration to the imprint material after bringing the imprint material and the mold into contact with each other.

14. A method of performing an imprint process of curing an imprint material supplied onto a substrate in a state in which the imprint material and a mold are brought into contact with each other, the method comprising:
bringing the imprint material supplied onto the substrate into contact with the mold;
positioning the substrate with respect to the mold in a direction parallel to a surface of the substrate while transmitting a vibration to the imprint material which is in contact with the mold; and
curing the imprint material on the positioned substrate.

15. A method of performing an imprint process of forming a pattern on a substrate by bringing a mold and an imprint material supplied onto the substrate into contact with each other,
wherein when moving the substrate relatively to the mold in a direction parallel to a surface of the substrate in a state in which the imprint material is uncured and brought into contact with the mold, a relationship between a force generated between the mold and the substrate, and a relative moved distance of the substrate in the direction is that the relative moved distance exhibits linearity in a first region but no linearity in a second region which is larger than the first region,
the method comprising:
bringing the imprint material supplied onto the substrate into contact with the mold;
moving the substrate relatively to the mold beyond a first position and to a second position within the second region in a state in which the imprint material and the mold contact with each other, and then relatively moving the substrate from the second position to the first position to position to the first position; and
curing the imprint material on the positioned substrate.
